(19) United States
(12) Patent Application Publication
(10) Pub. No.: US 2026/0271212 A1
(43) Pub. Date: Sep. 10, 2026

(54) EXPANSION CARD DEVICE

(71) Applicants: INVENTEC (PUDONG) TECHNOLOGY CORPORATION, Shanghai (CN); INVENTEC CORPORATION, Taipei City (TW)

(72) Inventor: Chang-Hsin CHIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/454,769

(22) Filed: Jan. 21, 2026

Related U.S. Application Data
(60) Provisional application No. 63/768,321, filed on Mar. 7, 2025.

(30) Foreign Application Priority Data
Aug. 11, 2025 (CN) 202511119348.7

(51) Int. Cl. H05K 7/14

(52) U.S. Cl. CPC H05K 7/1435; H05K 7/1407; H05K 7/1418; H05K 7/1461

(57) ABSTRACT

An expansion card device having a first height includes a housing and two expansion card assemblies. The housing includes two plates and a base. The base includes two assembly portions and a partition portion. The two assembly portions are respectively fixed to the two plates. Each of the two expansion card assemblies has a second height and includes a mounting bracket and an expansion card. The expansion card includes a circuit board assembly and a bracket. The circuit board assembly has an adjacent mounting surface and abutment surface. The bracket is disposed on the mounting surface of the circuit board assembly and includes a coupling portion, a part of which protrudes beyond the abutment surface and is assembled to the mounting bracket. The two expansion card assemblies are respectively disposed in the two accommodation spaces.

### CROSS-REFERENCE TO RELATED APPLICATIONS

This non-provisional application claims priority under 35 U.S.C. § 119(a) on Patent Application No(s). 63/768,321 filed in United States on Mar. 7, 2025 and Patent Application No(s). 202511119348.7 filed in China on Aug. 11, 2025, the entire contents of which are hereby incorporated by reference.

### BACKGROUND

### 1. Technical Field

This invention relates to an expansion card device, especially the expansion card device with two expansion card assemblies stacked in two opposite sides.

### 2. Related Art

Generally, an expansion card is configured in a server to expand the functions of the server. As the demand for the performance of servers increases, the number of expansion cards required to be configured in the server also increases. However, the internal space of the server is limited, and how to increase the number of expansion cards within the limited space is one of the problems that research and development personnel should solve.

### SUMMARY

The present invention provides an expansion card device to reduce the height of the space occupied by the expansion card device along the stacking direction, so that the expansion card device can be placed within the limited space of a server.

An expansion card device disclosed in an embodiment of the present invention has a first height and comprises a housing and two expansion card assemblies. The housing comprises two plates and a base. The base comprises two assembly portions and a partition portion. The two assembly portions are respectively connected to two opposite sides of the partition portion, and the two assembly portions protrude in opposite directions of the partition portion. The two assembly portions are respectively fixed to the two plates to define two accommodation spaces between the two plates. The two expansion card assemblies respectively have a second height, and each comprises a mounting bracket and an expansion card. The expansion card comprises a circuit board assembly and a bracket. The circuit board assembly comprises a mounting surface and an abutment surface adjacent to each other. The bracket is disposed on the mounting surface of the circuit board assembly, and the bracket comprises a coupling portion. A part of the coupling portion sticks out of the abutment surface along the direction of the height and is assembled to the mounting bracket. Wherein, the two expansion card assemblies are respectively located in the two accommodation spaces, the two abutment surfaces of the two expansion card assemblies both face the base, and the two coupling portions of the two brackets are respectively adjacent to the two plates and are staggered from each other, resulting in an overlapping region of a third height in a height direction.

According to the expansion card device disclosed in the above embodiments, since the two abutment surfaces of the two expansion card assemblies both face the base and are stacked in an inverted manner, the two more protruding coupling portions of the two brackets are respectively adjacent to the two plates and are staggered from each other. In this way, the extra space in the expansion card assembly can be effectively utilized to accommodate the more protruding coupling portion of the bracket, thereby reducing the stacking size of the expansion card device and allowing the expansion card device to be placed within the limited space of the server.

The above description of the content of the present invention and the following description of the embodiments are used to demonstrate and explain the principles of the present invention, and to provide further explanation of the scope of the patent application of the present invention.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective schematic view of an expansion card device according to an embodiment of the present invention;

FIG. 2 is an exploded schematic view of an expansion card device in FIG. 1;

FIG. 3 is an exploded schematic view of a housing in FIG. 2;

FIG. 4 is an exploded schematic view of the expansion card assembly in FIG. 2;

FIG. 5 to FIG. 7 are schematic views showing the assembly of an expansion card assembly and the housing according to an embodiment of the present invention; and

FIG. 8 is a side schematic view of an expansion card device in FIG. 1.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

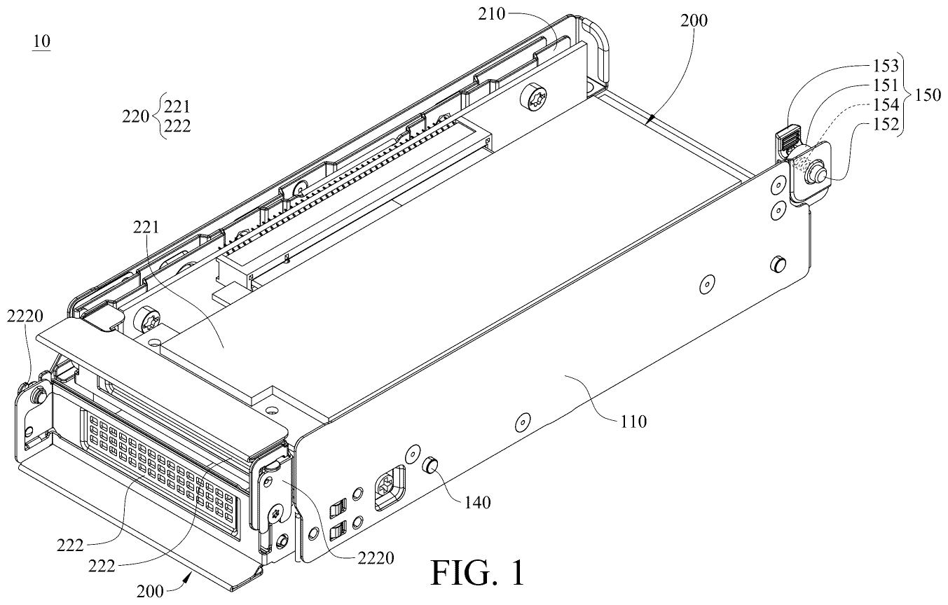

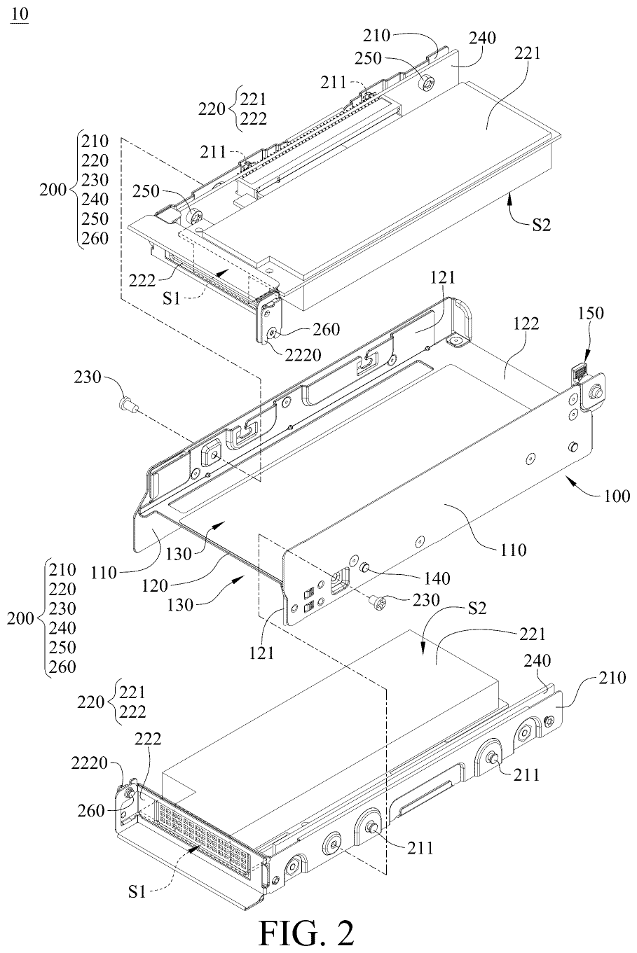

Please refer to FIG. 1 and FIG. 2. FIG. 1 is a perspective schematic view of an expansion card device 10 according to an embodiment of the present invention. FIG. 2 is an exploded schematic view of an expansion card device 10 in FIG. 1. In this embodiment, the expansion card device 10 is, for example, placed in a chassis (not shown) of a server (not shown). The height of the chassis of the server is, for example, 1U. The expansion card device 10 includes a housing 100 and two expansion card assemblies 200. The housing 100 includes two plates 110 and a base 120. Two opposite sides of the base 120 are respectively connected to the two plates 110 to define two accommodation spaces 130 between the two plates 110.

In this embodiment, the two expansion card assemblies 200 include a mounting bracket 210 and an expansion card 220. The expansion card 220 is, for example but not limited to, a Low Profile Peripheral Component Interconnect Express (PCIe) interface card, and includes a circuit board assembly 221 and a bracket 222. The circuit board assembly 221 is, for example, a printed circuit board assembly (PCBA). The circuit board assembly 221 includes a mounting surface S1 and an abutment surface S2 adjacent to each other. The bracket 222 is, for example, made by iron, and is disposed on the mounting surface S1 of the circuit board assembly 221. The bracket 222 includes a coupling portion 2220. A part of the coupling portion 2220 sticks out of the abutment surface S2 along the direction of the height, and is assembled to the mounting bracket 210. The two expansion card assemblies 200 are respectively located in the two accommodation spaces 130, and the two abutment surfaces S2 of the two expansion card assemblies 200 both face the base 120. The two coupling portions 2220 of the two brackets 222 are respectively adjacent to the two plates 110 and are staggered from each other.

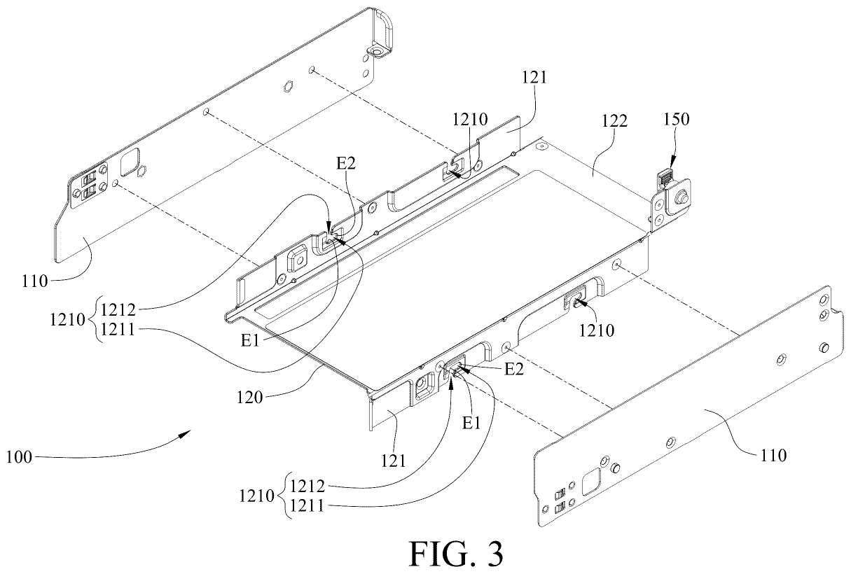

Please refer to FIG. 3. FIG. 3 is an exploded schematic view of the housing 100 in FIG. 2. In this embodiment, the base 120 includes two assembly portions 121 and a partition portion 122. The two assembly portions 121 are respectively connected to two opposite sides of the partition portion 122, and the two assembly portions 121 protrude in opposite directions of the partition portion 122. The two assembly portions 121 are respectively fixed to the two plates 110, and each includes a plurality of assembly slots 1210.

In this embodiment, the plurality of assembly slots 1210 each include an assembly segment 1211 and an open segment 1212. The assembly segment 1211 has an opposite connecting open end part E1 and a close end part E2. The open segment 1212 is substantially perpendicular to the connecting open end part E1 of the assembly segment 1211, and the open segment 1212 is connected to the connecting open end part E1 of the assembly segment 1211, so that the corresponding assembly pin 211 can slide from the open segment 1212 into the connecting open end part E1 of the assembly segment 1211, and slide from the connecting open end part E1 of the assembly segment 1211 to the close end part E2 of the assembly segment 1211.

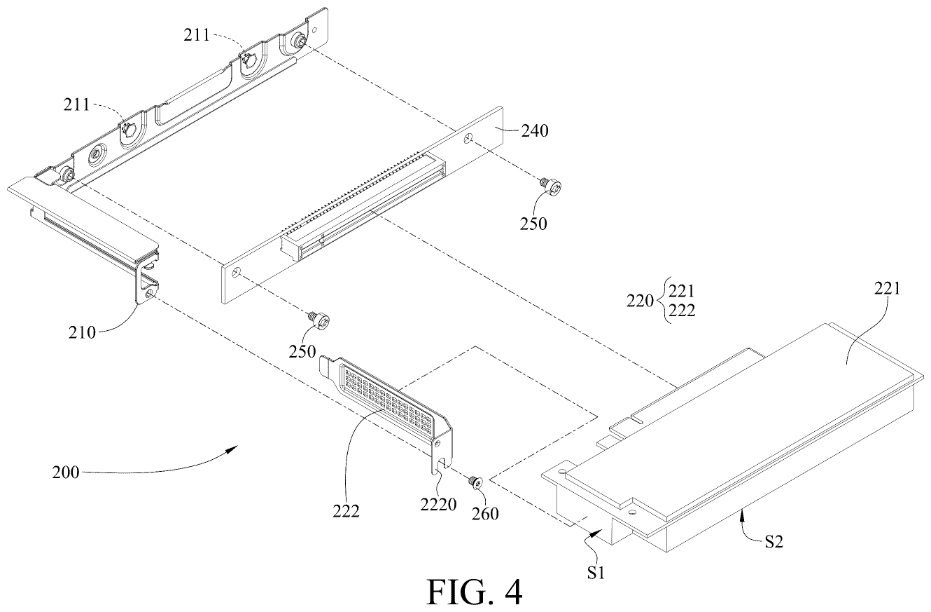

Please refer to FIG. 4. FIG. 4 is an exploded schematic view of the expansion card assembly 200 in FIG. 2. In this embodiment, the two mounting brackets 210 of the two expansion card assemblies 200 each comprise a plurality of assembly pins 211, and the plurality of assembly pins 211 are respectively and slidably installed in the plurality of assembly slots 1210. The plurality of assembly pins 211 and the plurality of assembly slots 1210 may be, for example, assemble with each other, but are not limited thereto.

The two expansion card assemblies 200 each comprise a first fastener 230. The two mounting brackets 210 are respectively fixed to the two plates 110 through the two first fasteners 230, so as to hold the plurality of assembly pins 211 of the two mounting brackets 210 at the close end parts E2 of the assembly segments 1211. Wherein, the first fastener 230 may be, for example, a screw, but is not limited thereto.

The two expansion card assemblies 200 each comprise two riser cards 240 and a plurality of second fasteners 250. The two riser cards 240 are respectively fixed to the two mounting brackets 210 through the plurality of second fasteners 250. The two card bodies 221 of the two expansion cards 220 are respectively electrically connected to and installed on the two riser cards 240. In other embodiment, the two riser cards 240 may be replaced by one or more cables.

The two expansion card assemblies 200 each comprise a third fastener 260. The third fastener 260 is fastened to the coupling portion 2220 of the corresponding bracket 222 and the mounting bracket 210. Wherein, the third fastener 260 may be, for example, a screw, but is not limited thereto.

In this embodiment (as shown in FIG. 1), the housing 100 may further comprise a plurality of sliders 140. The plurality of sliders 140 are respectively disposed on a side of each of the two plates 110 located away from the base 120. The plurality of sliders 140 are configured to be slidably disposed in a slide slot (not shown) of the chassis and are configured to guide the housing 100 to accurately slide into the chassis.

The housing 100 may further comprise a holding mechanism 150. The holding mechanism 150 is disposed on one of the plates 110 and is configured for holding the housing 100 on the chassis.

The holding mechanism 150 comprises a fixed component 151, an assembling pin 152, and a handheld part 153. The fixed component 151 is fixed to the corresponding plate 110. The assembling pin 152 is movably disposed on the fixed component 151. The handheld part 153 is pivotally connected to the assembling pin 152 and configured to be moved to force the assembling pin 152 to move relative to the fixed component 151. However, the holding mechanism 150 is not limited to the above-mentioned form; for example, the assembling pin may also be replaced by a flange.

The holding mechanism 150 further comprises a restoring component 154. The restoring component 154 is connected to the fixed component 151 and the assembling pin 152 and configured to push the assembling pin 152 to stick out of the outer side of the plate 110. Wherein, the outer side of the plate 110 may face away from the base 120.

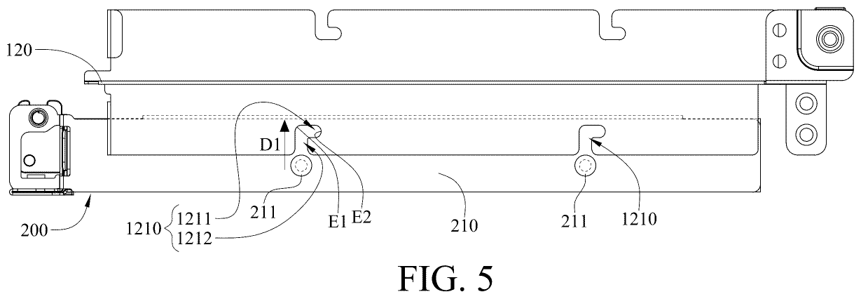

Please refer to FIG. 5 to FIG. 7. FIG. 5 to FIG. 7 are assembly schematic views of the expansion card assembly 200 being installed on the housing 100 according to an embodiment of the present invention. Hereinafter, the installation process for fixing the expansion card assembly 200 to the housing 100 will be described.

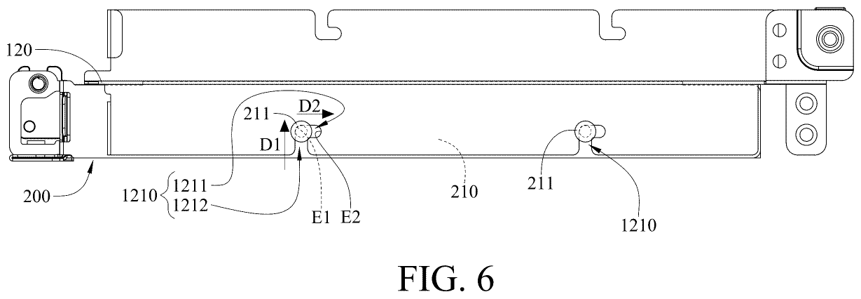

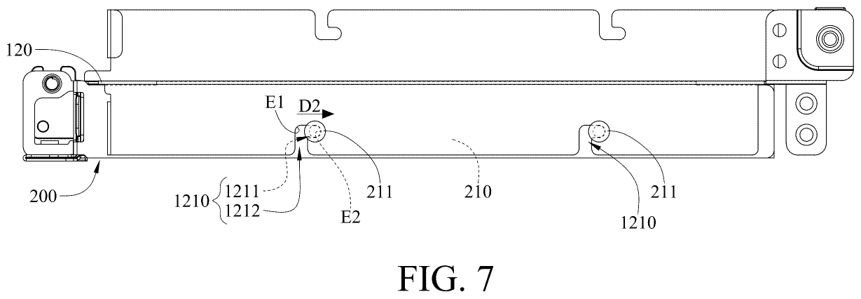

The installation process of the expansion card assembly 200 located below the partition portion 120 is described first. First, as shown in FIG. 5 and FIG. 6, the plurality of assembly pins 211 of the mounting bracket 210 of the lower expansion card assembly 200 are respectively placed into the open segments 1212 of the plurality of assembly slots 1210 of the base 120, and the plurality of assembly pins 211 are moved to slide along a direction D1 from the open segment 1212 to the connecting open end part E1 of the assembly segment 1211 of the assembly slot 1210. Next, as shown in FIG. 7, the plurality of assembly pins 211 are slid along a direction D2 from the connecting open end part E1 of the assembly segment 1211 to the close end part E2 of the assembly segment 1211. Then, the expansion card assembly 200 is fixed to the plate 110 through the first fastener 230 (as shown in FIG. 2) to fix the expansion card assembly 200 to the base 120. In this way, the assembly between the lower expansion card assembly 200 and the base 120 is completed. Similarly, the assembly between the upper expansion card assembly 200 and the base 120 is completed according to the above installation process. Since the installation process between the upper expansion card assembly 200 and the base 120 is the same as that in the above description, it will not be repeated.

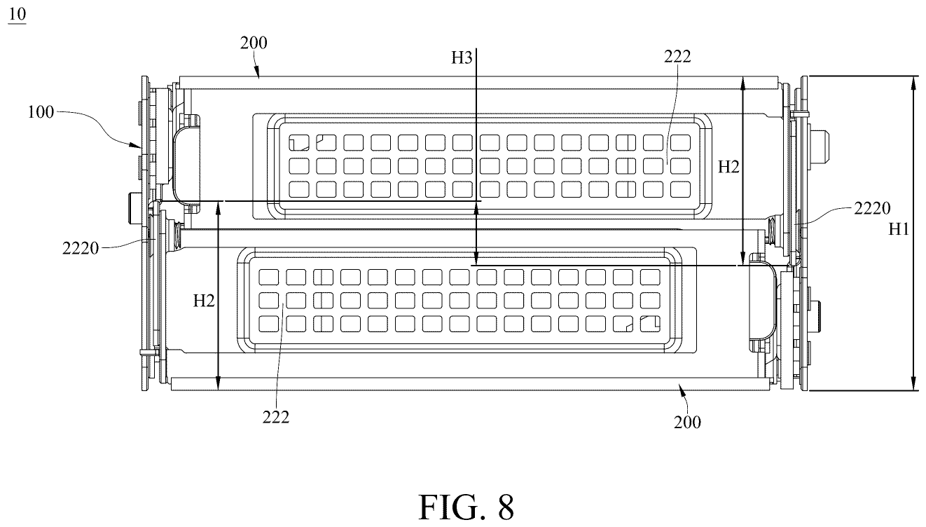

Please refer to FIG. 8. FIG. 8 is a side schematic view of an expansion card device 10 in FIG. 1. In this embodiment, the expansion card device 10 has a first height H1, and the two expansion card assemblies 200 respectively have a second height H2. The two expansion card assemblies 200 are respectively stacked on two opposite sides of the housing 100. Since the coupling portions 2220 of the brackets 222 in the two expansion card assemblies 200 are staggered, there is an overlapping space of a third height H3 in the height direction that is overlapped with both of the two expansion card assemblies 200. Therefore, the first height H1 of the expansion card device 10 is the sum of the second heights (H2+H2) of the two expansion card assemblies 200 minus the third height H3 of the overlapping region of the two expansion card assemblies 200. The second height H2 of the expansion card assembly 200 is the height of the expansion card assembly 200 at the coupling portion 2220 of the bracket 222, which is the maximum height of the expansion card assembly 200. Compared with a situation where two expansion card assemblies 200 are both stacked on one side of the housing 100, the total height of the two stacked expansion card assemblies 200 would be the sum of the second heights (H2+H2) of the two expansion card assemblies 200. That is to say, the arrangement of the two expansion card assemblies 200 on two opposite sides of the housing 100 in this embodiment can effectively reduce the height of the expansion card device 10 from H2+H2 to H2+H2−H3, enabling it to be installed into a 1U server having limited space.

The assembled expansion card device 10 has a first height H1 obtained by subtracting the third height H3 of the overlapping brackets 222 of the two expansion cards 220. The first height H1 is smaller than the sum of the second heights (H2+H2) of the brackets 222 before the two expansion cards 220 are assembled, making the first height H1 to be more easily designed to be less than 1U. In this way, the number of expansion cards can be increased within a limited space.

According to the expansion card device of the above embodiments, the two expansion card assemblies can be respectively located in the two accommodation spaces, the two abutment surfaces of the two expansion card assemblies both face the base, and the two coupling portions of the two brackets are respectively adjacent to the two plates, so they can be staggered from each other to achieve the effect of preventing the expansion cards from affecting each other when the coupling portions of the brackets in the two expansion card assemblies are staggered. In this way, the arrangement of the two expansion card assemblies on two opposite sides of the housing in this embodiment can effectively reduce the height of the expansion card device, enabling it to be installed into a server having limited space.

The expansion card device of the present disclosure can be installed in a server. The server can be used for Artificial Intelligence (AI) computing, edge computing, or as a 5G server, cloud server, or Internet of Vehicles (IoV) server.

Although the present invention has been disclosed as above with the aforementioned embodiments, they are not intended to limit the present invention. Any person skilled in the art can make some modifications and refinements without departing from the spirit and scope of the present invention. Therefore, the scope of patent protection of the present invention shall be determined by the scope of the appended claims.

What is claimed is:

1. An expansion card device, having a first height, comprising:
a housing, comprising two plates and a base, wherein the base comprises two assembly portions and a partition portion, the two assembly portions respectively connect to two opposite sides of the partition portion, and the two assembly portions protrude in opposite directions of the partition portion, the two assembly portions respectively fix to the two plates to define two accommodation spaces between the two plates; and
two expansion card assemblies, each having a second height and comprising:
a mounting bracket; and
an expansion card, comprising a circuit board assembly and a bracket, wherein the circuit board assembly comprises a mounting surface and an abutment surface adjacent to each other, the bracket dispose on the mounting surface of the circuit board assembly, and the bracket comprises a coupling portion, and a part of the coupling portion sticks out of the abutment surface and assembled to the mounting bracket;
wherein the two expansion card assemblies are respectively located in the two accommodation spaces, the two abutment surfaces of the two expansion card assemblies both face the base, and the two coupling portions of the two brackets are respectively adjacent to the two plates and are staggered from each other, forming an overlapping region of a third height in a height direction.

2. The expansion card device according to claim 1, wherein the two assembly portions each comprise a plurality of assembly slots, the two mounting brackets of the two expansion card assemblies each comprise a plurality of assembly pins, and the plurality of assembly pins are respectively and slidably installed in the plurality of assembly slots.

3. The expansion card device according to claim 2, wherein the plurality of assembly slots each comprise an assembly segment and an open segment, the assembly segment has an opposite open end and a locating end, the open segment is substantially perpendicular to the connecting open end part of the assembly segment, and the open segment is connected to the open end of the assembly segment, so that the corresponding assembly pin can slide from the open segment into the open end of the assembly segment, and slide from the open end of the assembly segment to the locating end of the assembly segment.

4. The expansion card device according to claim 3, wherein the two expansion card assemblies each comprise a first fastener, the two mounting brackets are respectively fixed to the two plates through the two first fasteners, so as to hold the assembly pins of the two mounting brackets at the locating ends of the assembly segments.

5. The expansion card device according to claim 4, wherein the two expansion card assemblies each comprise two riser cards and a plurality of second fasteners, the two riser cards are respectively fixed to the two mounting brackets through the plurality of second fasteners, and the two card bodies of the two expansion cards are respectively installed on the two riser cards.

6. The expansion card device according to claim 5, wherein the two expansion card assemblies each comprise a third fastener, and the third fastener is fixed to the coupling portion of the corresponding bracket and the mounting bracket.

7. The expansion card device according to claim 1, wherein the housing further comprises a plurality of sliders, the plurality of sliders are respectively disposed on sides of the two plates located away from the base, and the plurality of sliders are configured to be slidably disposed in a slide slot.

8. The expansion card device according to claim 1, further comprising a holding mechanism, wherein the holding mechanism is disposed on one of the plates and configured for holding the housing on a chassis.

9. The expansion card device according to claim 1, wherein the first height is the sum of the second heights of the two expansion card assemblies minus the third height of the overlapping region of the two expansion card assemblies.

10. The expansion card device according to claim 1, wherein the second height of the expansion card assembly is a height of the coupling portion of the bracket, which is a maximum height of the expansion card assembly.
